(19) United States
(12) Patent Application Publication
(10) Pub. No.: US 2026/0237429 A1
(43) Pub. Date: Aug. 13, 2026

(54) MEMORY DEVICES WITH SELECTIVELY COUPLED WRITE ASSIST CIRCUIT AND METHODS FOR OPERATING THE SAME

(71) Applicant: Taiwan Semiconductor Manufacturing Company, Ltd., Hsinchu (TW)

(72) Inventors: Yi-Hsin Nien, Hsinchu (TW); Hidehiro Fujiwara, Hsinchu (TW); Chih-Yu Lin, Hsinchu (TW); Yen-Huei Chen, Hsinchu (TW)

(73) Assignee: Taiwan Semiconductor Manufacturing Company, Ltd., Hsinchu (TW)

(21) Appl. No.: 19/191,485

(22) Filed: Apr. 28, 2025

Related U.S. Application Data
(60) Provisional application No. 63/755,578, filed on Feb. 7, 2025.

(51) Int. Cl. G11C 11/418

(52) U.S. Cl. CPC G11C 11/418

(57) ABSTRACT

A memory circuit includes a first memory array comprising a plurality of first memory cells, each of which is configured to operate with a first supply voltage; a second memory array comprising a plurality of second memory cells, each of which is configured to operate with a second supply voltage, the first supply voltage and the second supply voltage being different from each other; and a driver operatively coupled to the plurality of first memory cells and the plurality of second memory cells through a first access line and a second access line, respectively. The driver is configured to selectively provide a negative voltage on one of the first access line or the second access line based on an address signal.

### CROSS-REFERENCE TO RELATED APPLICATION

This application claims priority to and the benefit of U.S. Provisional Application No. 63/755,578, filed Feb. 7, 2025, which is incorporated herein by reference in its entirety for all purposes.

### BACKGROUND

Static random access memory (SRAM) is a type of semiconductor memory used in computing applications that require, for example, high-speed data access. For example, cache memory applications use SRAMs to store frequently-accessed data, e.g., data accessed by a central processing unit.

The SRAM's cell structure and architecture enable high-speed data access. The SRAM cell includes a bi-stable flip-flop structure including, for example, four to eight transistors. An SRAM architecture can include one or more arrays of memory cells and support circuitry. Each of the SRAM arrays is arranged in rows and columns called “word lines” and “bit lines,” respectively. The support circuitry includes address and driver circuits to access each of the SRAM cells via the word lines and bit lines for various SRAM operations.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory device including a write assist circuit, in accordance with some embodiments.

FIG. 2 illustrates a schematic view of one of the memory cells of the memory device of FIG. 1, in accordance with some embodiments.

FIG. 3 illustrates an example schematic diagram of a portion of the memory device of FIG. 1, in accordance with some embodiments.

FIG. 4 illustrates a circuit diagram of a portion of the memory device of FIG. 1 that is implemented based on the schematic diagram of FIG. 3, in accordance with some embodiments.

FIG. 5 illustrates another example schematic diagram of a portion of the memory device of FIG. 1, in accordance with some embodiments.

FIG. 6 illustrates yet another example schematic diagram of a portion of the memory device of FIG. 1, in accordance with some embodiments.

FIG. 7 illustrates example waveforms of various signals while operating the memory device of FIG. 1, in accordance with some embodiments of the present disclosure.

FIG. 8 illustrates an example schematic diagram of the write assist circuit of the memory device of FIG. 1, in accordance with some embodiments of the present disclosure.

FIG. 9 illustrates a cross-sectional view of an example semiconductor device, which may be a portion of an implementation of the memory device of FIG. 1, in accordance with some embodiments.

FIG. 10 illustrates an example flowchart of a method for fabricating a portion of the memory device of FIG. 1, in accordance with some embodiments.

FIG. 11 illustrates an example flowchart of a method for operating the memory device of FIG. 1, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The following disclosure describes various aspects of a memory device or circuit, e.g., a static random access memory (SRAM) device. For example, the disclosure describes different embodiments related to an SRAM memory write operation. For ease of explanation, certain SRAM circuit elements and control logic are disclosed to facilitate in the description of the different embodiments. It should be appreciated that SRAM devices also include other circuit elements and control logic. These other circuit elements and control logic are within the spirit and scope of this present disclosure.

Typically, an SRAM device includes an array of individual SRAM cells. Each SRAM cell can store a binary voltage value therein, which voltage value represents a logic data bit (e.g., “0” or “1”). One existing configuration for an SRAM cell includes a pair of cross-coupled devices such as inverters. With complementary metal oxide semiconductor (CMOS) technology, each of the inverters generally includes a pull-up PFET (p-channel) transistor connected to a complementary pull-down NFET (n-channel) transistor. The inverters, connected in a cross-coupled configuration, act as a latch that stores the data bit therein so long as power is supplied to the memory array. In a conventional six-transistor (6T) cell, a pair of access transistors or pass gates (when activated by a word line) selectively couples the inverters to a pair of complementary bit lines. Other SRAM cell designs may include a different number of transistors, e.g., 4T, 8T, etc.

The design of SRAM cells has traditionally involved a compromise between the read and write functions of the memory cell to maintain cell stability, read performance and write performance. The transistors which make up the cross-coupled latch tend to be weak enough to be overdriven during a write operation, while also strong enough to maintain their data value when driving a bit line during a read operation. The access transistors that connect the cross-coupled cell nodes to the true and complement bit lines affect both the stability and performance of the cell. In one-port SRAM cells, a single pair of access transistors is conventionally used for both read and write access to the cell. The gates are driven to a digital value in order to switch the transistors between an on state and off state. The optimization of an access for a write operation would drive the reduction of the on-resistance (Rₒₙ) for the device. On the other hand, the optimization of an access transistor for a read operation drives an increase in Rₒₙ in order to isolate the cell from the bit line capacitance and prevent a cell disturb.

One proposed approach to improve write performance of SRAM devices is to use so-called “negative boosting” techniques to discharge a bit line to a voltage level below the nominal low supply rail value (e.g., ground). Alternatively stated, the corresponding bit line of an SRAM cell may present a negative voltage, when being written. Such a bit line is typically discharged to the negative voltage through a write assist circuit that typically includes a capacitor (sometimes referred to as a boost capacitor). In this way, the pass gates of the SRAM cell coupled to the discharged bit line see a resultant increase in both the gate-to-source and drain-to-source voltages. This negative boosting may allow for an increased margin of 3 σ or more (in terms of expected device failures) as compared to more conventional write techniques, wherein the bit line is simply discharged to the value of the nominal low voltage rail (e.g., ground).

Notwithstanding the benefits of negative boosting, the existing SRAM devices with negative boosting may still not be entirely satisfactory in certain aspects. For example, with the ever progressively shrunk size of transistors in advanced technology nodes, multiple memory banks are generally coupled to the write assist circuit, where some of the memory banks may operate with a relatively high supply voltage and others of the memory banks may operate with a relatively low supply voltage concerning the power consumption. In general, the memory bank, e.g., selected to operate with the high supply voltage, is configured for high-speed read/write operation, and the memory bank, e.g., selected to operate with the low supply voltage, is configured for data retention.

Under a configuration where a first memory bank (operating with the low supply voltage) is physically located closer to the write assist circuit than a second memory bank (operating with the high supply voltage), in order for efficiently writing the first memory bank with a negative bit line, the write assist circuit generally provides a “deeper” negative voltage on the bit line to assure that the first memory bank receives a negative enough voltage on the bit line. As a non-limiting example where the high and low supply voltages are equal to about 1.1 V and 0.5 V, respectively, the write assist circuit may apply a negative voltage of around −250 mV on a discharging bit line, which is connected to both the first (far) memory bank and second (near) memory bank. Accordingly, the first memory bank is able to see a negative voltage of around −50 mV on its bit line, which may cause the second memory bank to see a negative voltage close to −250 mV on its bit line. This results in access transistors of the second memory bank to be accidentally turned on, due to V_{gs} of the access transistors being too close to their Vₜₕ. As such, the second memory bank may disadvantageously lose the capability of retaining stored data.

The present disclosure provides various embodiment of a memory circuit including a (write) driver that can provide a negative voltage on a bit line, sometime referred to as a negative bit line voltage. The memory circuit can include an SRAM device or circuit. The negative bit line voltage can be selectively coupled (or applied) to a first bit line of a first memory bank of the disclosed memory circuit selected to be an active memory bank, while the negative bit line voltage can be selectively isolated from a second bit line of a second memory bank of the disclosed memory circuit selected to be an inactive memory bank. For example, the memory circuit, as disclosed herein, can include a logic gate, at least a first multiplexer (e.g., a first transistor), and at least a second multiplexer (e.g., a second transistor). The first multiplexer is coupled between the write driver and the first bit line, and the second multiplexer is coupled between the write driver and the second bit line. Based on a received address signal, the logic gate can activate one of the first or second multiplexer, while deactivating the other of the first or second multiplexer. In some embodiments, the active memory bank may be configured for high-speed read/write operation or operating with a relatively high supply voltage, and the inactive memory bank may be configured for data retention or operating with a relatively low supply voltage. In some embodiments, the inactive memory bank (operating with the lower supply voltage) may be physically located closer to the write driver than the active memory bank (operating with the higher supply voltage). Under such an arrangement, the first bit line, coupling the write driver to the active memory bank, can fly over the inactive memory bank through physically constituting the first bit line with multiple metal tracks in different metallization layers.

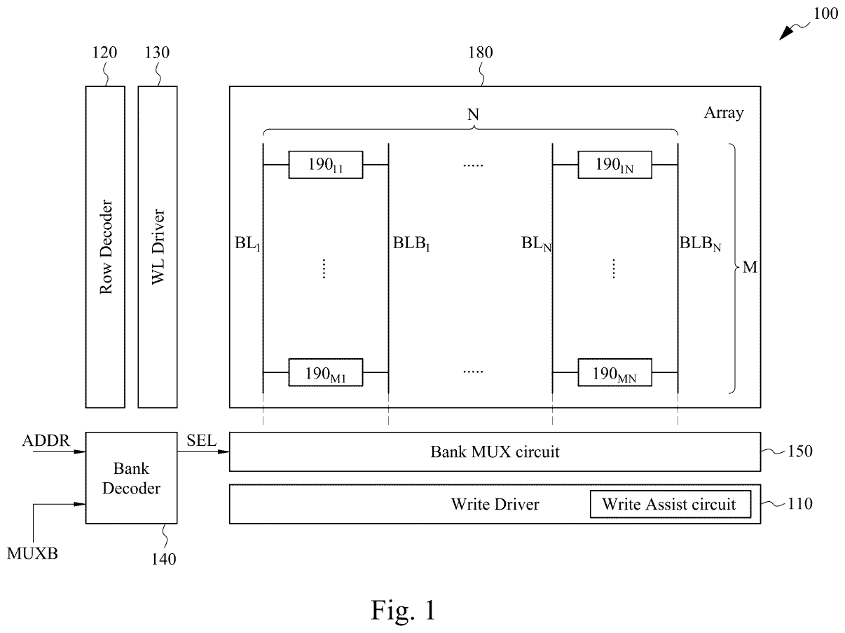

FIG. 1 illustrate a block diagram of an example static random access memory (SRAM) device/circuit 100 with a write driver 110 that includes a write assist circuit, according to various embodiments of the present disclosure. The SRAM device 100 can further include a row decoder 120, a word line driver 130, a bank decoder 140, a bank multiplexer circuit 150, and a memory array 180. It should be understood that the block diagram of FIG. 1 is provided for illustrative purposes and has been simplified, and thus, the SRAM device 100 can include any of various other suitable components while remaining within the scope of the present disclosure.

The memory array 180 includes a number of memory cells 190. The memory cells 190 can be arranged as a plural number of memory banks, some of which may be configured as active memory banks and some of which may be configured as inactive memory banks, which will be discussed in further detail below. In the illustrated example of FIG. 1, the memory array 180 has “M” rows (e.g., ROW₁ to ROW_{M}) and “N” columns (COL₁ to COL_{N}). As a non-limiting example, M may be equal to 256, and accordingly, the memory array 180 may include a first memory bank with 128 rows, and a second memory bank with 128 rows. Each of the memory cells 190 can be located at the intersection of a corresponding one of the rows and a corresponding one of the columns. Accordingly, the notation “190₁₁” refers to one of the memory cells 190 located in ROW₁ and COL₁, the notation “190_{MN}” refers to another one of the memory cells 190 located in ROW_{M} and column COL_{N}, and so on.

According to various embodiments of the present disclosure, based on an address (ADDR) signal, the bank decoder 140 can provide a bank selection (SEL) signal to the bank multiplexer circuit 150. Using the SEL signal, the bank multiplexer circuit 150 can select at least one of the memory banks (of the memory array 180) as an active memory bank and at least one of the memory banks (of the memory array 180) as an inactive memory bank. The active memory bank may be powered by a relatively high supply voltage for high-speed write/read operations, and the inactive memory bank may be powered by a relatively low supply voltage for retaining previously written data. The memory cells 190 of the active memory bank, selected by the bank multiplexer circuit 150, can be accessed (e.g., written) by the write driver 110. The write assist circuit of the write driver 110 can provide a negative bit line voltage and apply it on one or more bit line pairs of the active memory bank. The bit line pair are typically referred to as BL and BLB, in which the notation “BL” refers to a bit line, and the notation “BLB” refers to the complement of BL which is sometimes referred to as a bit line bar.

On the other hand, the memory cells 190 of the inactive memory bank, selected by the bank multiplexer circuit 150, may be operatively isolated from the write driver 110, causing bit line pairs of the inactive memory bank to be floating (e.g., after being pre-charged to the corresponding supply voltage). Prior to, concurrently with, or subsequently to selecting the active memory bank, each of the memory cells 190 can be accessed, e.g., for a read or write operation, using the ADDR signal. Based on the ADDR signal, the row decoder 120 can select a row (e.g., one of the ROW₁ to ROW_{M}) of the memory cells of the active memory bank to access via the word line driver 130 (e.g., a corresponding one of a number of word line drivers 130₁ . . . 130_{M}).

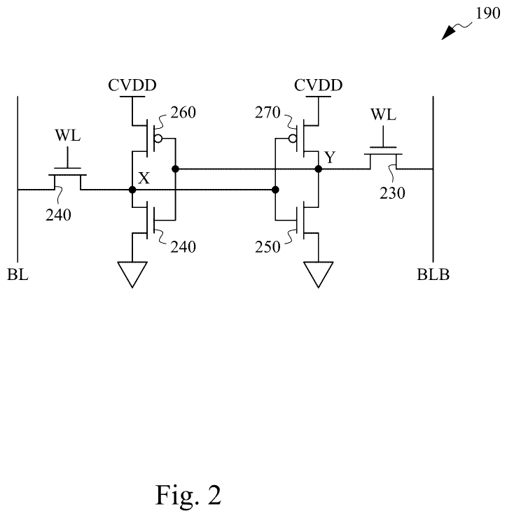

The memory cell 190 can have any of various circuit topologies. For example, the memory cell 190 can have a “6T” circuit topology. FIG. 2 illustrates an example 6T circuit topology for the memory cell 190. The 6T circuit topology includes n-channel metal-oxide-semiconductor (NMOS) pass-gate devices 220 and 230, NMOS pull-down devices 240 and 250, and p-channel metal-oxide-semiconductor (PMOS) pull-up devices 260 and 270. A voltage from the word line driver 130 controls (e.g., turns on/off) the NMOS devices 220 and 230 through a word line WL, so as to pass voltages from the bit line pair, BL and BLB, to a bi-stable flip-flop structure formed by the NMOS devices 240 and 250 and the PMOS devices 260 and 270. The NMOS device 240 and PMOS device 260 form a first inverter, and the NMOS device 250 and PMOS device 270 form a second inverter, in which the first and second inverters are cross-coupled to each other operatively forming the flip-flop structure. The voltage applied on the bit line pair BL and BLB can be used for a write operation.

For example, when the voltage applied on the word line WL (or to the gate terminals of the NMOS pass-gate devices 220 and 230) is at a sufficient voltage level, the BL's logic value and the BLB's logic value can be passed to the bi-stable flip-flop structure. As a non-limiting example, upon the NMOS pass-gate devices 220 and 230 being turned on, if the bit line bar BLB is provided with a ‘1’ or a logic high value (e.g., a power supply voltage CVDD such as 0.4V, 0.5V, 0.6V, 0.7V, 1.0V, 1.1V, 1.2V, 1.8V, 2.4V, 3.3V, 5V, or any combination thereof), and the bit line BL is provided with a ‘0’ or a logic low value (e.g., ground or 0V), the BL's logic low value and the BLB's logic high value can be passed to internal nodes, X and Y, of the bi-stable flip-flop structure, respectively. As a result, these logic values are written (or programmed) into the bi-stable flip-flop structure.

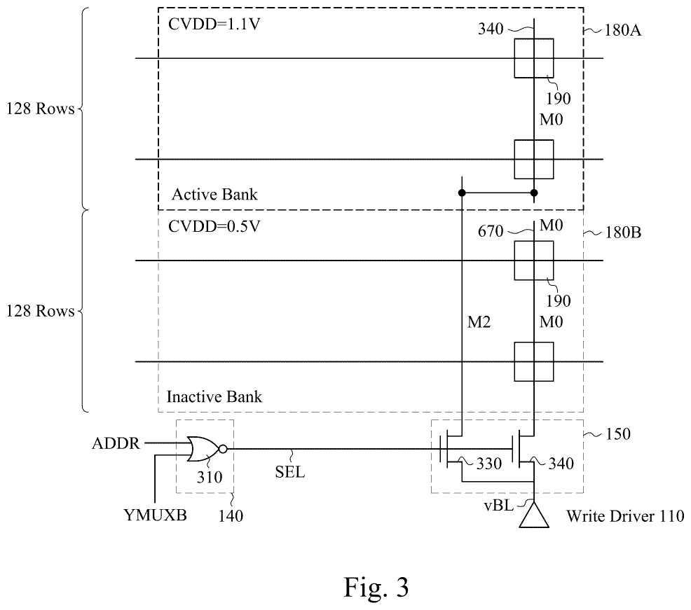

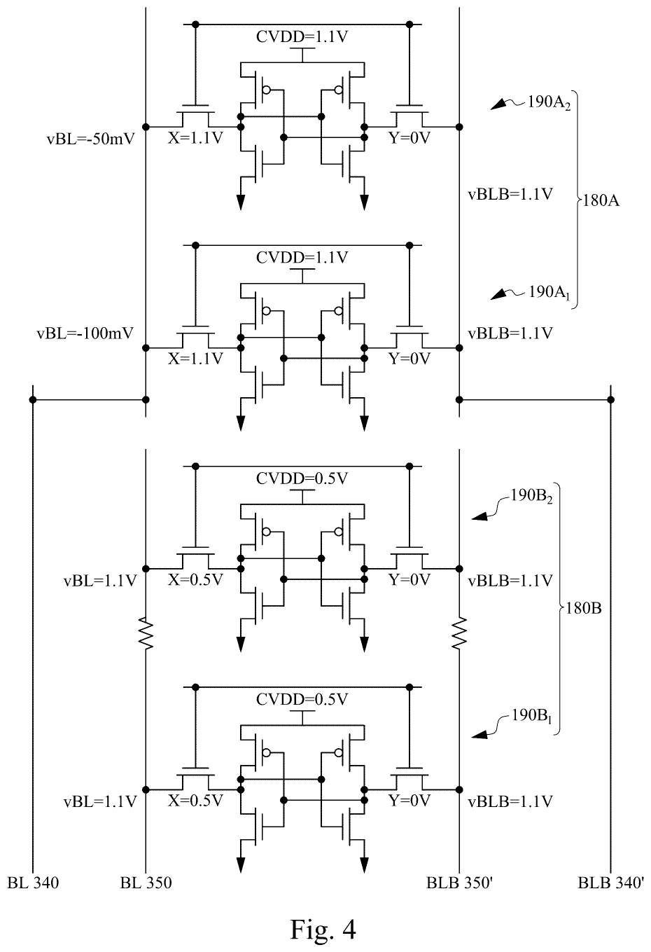

FIG. 3 illustrates an example schematic diagram of a portion of the SRAM device 100 (FIG. 1), with FIG. 4 illustrating a circuit diagram constructed based on the schematic diagram of FIG. 3, in accordance with some embodiments of the present disclosure. In the example of FIGS. 3-4, two memory banks, e.g., 180A and 180B, are included in the memory array 180, one of which can be selected as an active one and the other of which can be selected as an inactive one. For example, the memory array 180 may include 256 rows (or 256 word lines), in which the memory bank 180A with 128 rows is selected as the active memory bank (e.g., operating with CVDD of about 1.1V) and the memory bank 180B with 128 rows is selected as the inactive memory bank (e.g., operating with CVDD of about 0.5V).

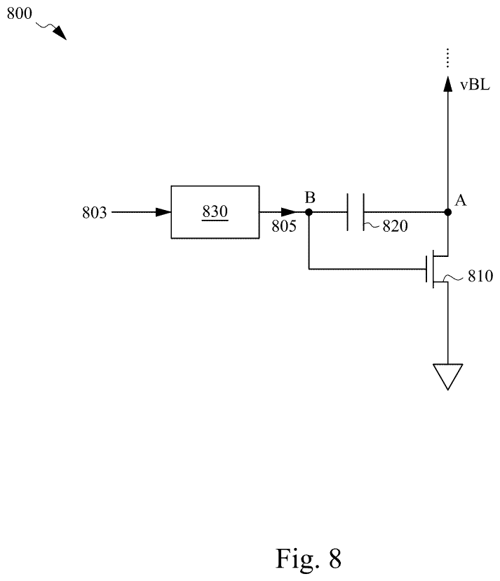

In some embodiments, the write assist circuit of the write driver 110 can provide a vBL signal to the memory array 180. For example, the write driver 110 can selectively provide the vBL signal as a negative bit line voltage for the active memory bank (e.g., 180A) based on the ADDR signal. The write assist circuit of the write driver 110 can include one or more boost capacitors so as to provide such a negative vBL signal, which will be discussed below with respect to FIG. 8. The negative vBL signal can be applied to at least one bit line BL (e.g., 340) that is coupled to a number of the memory cells 190 of the active memory bank 180A through a multiplexer 320 of the bank multiplexer circuit 150. The multiplexer 320 (e.g., implemented as an NMOS device) can be turned on by the SEL signal generated by a logic gate 310 of the bank decoder 140. For example, the logic gate 310 may include a NOR gate having a first input configured to receive the ADDR signal, a second input configured to receive a control (YMUXB) signal, and an output configured to generate the SEL signal by NOR'ing the ADDR signal and the YMUXB signal. The multiplexer 320 has a gate terminal connected to the output of the logic gate 310, a first source/drain terminal connected to the write driver 110, and a second source/drain terminal connected to the bit line BL 340.

Although not shown, while the negative vBL signal being applied on the bit line BL 340, a corresponding bit line bar BLB of the same column may be floating (e.g., remaining at a pre-charged voltage level). This may apply to the case where a logic low value and a logic high value are programmed into the internal nodes X and Y, respectively (FIG. 2). In another case where a logic high value and a logic low value are programmed into the internal nodes X and Y, respectively, the negative vBL signal may be applied to the corresponding bit line BLB, with the bit line BL 340 being floating.

Concurrently with the write driver 110 being coupled to the bit line BL 340 through the turned-on multiplexer 320, the negative vBL signal may be isolated from a bit line BL (e.g., 350) that is coupled to a number of the memory cells 190 of the inactive memory bank 180B. The bit line BL 350 can be isolated from the write driver 110 through turning off a multiplexer 330 of the bank multiplexer circuit 150. The multiplexer 330 (e.g., implemented as another NMOS device) can be turned off by the SEL signal. For example, the multiplexer 330 has a gate terminal connected to the output of the logic gate 310, a first source/drain terminal connected to the write driver 110, and a second source/drain terminal connected to the bit line BL 350. Although not shown, a corresponding bit line bar BLB of the same column may also be isolated from the write driver 110. As such, the bit line pair, BL (350) and BLB, can be floating or remain at the pre-charged voltage level.

In the illustrative example of FIG. 3 where the memory array 180 has 256 rows, the ADDR signal may be provided or inputted with 8 bits, e.g., ADDR[7:0]. One of these 8 bits can be utilized to identify whether the corresponding memory banks is configured as an active memory bank. For example, the YMUXB signal may be provided as an inverse pulse when a certain column of the memory array 180 is selected, that is, the YMUXB signal being pulled down to logic 0 when selecting a certain column. Further, when ADDR[7] is provided with logic 0 and ADDR[6] is provided with logic 1, the logic gate 310 can perform a NOR operation on the ADDR signal and the YMUXB signal to output the SEL signal including a first bit at logic 1 and a second bit at logic 0. The first bit can be received by the gate terminal of the multiplexer 320, and the second bit can be received by the gate terminal of the multiplexer 330. Accordingly, the multiplexer 320 is turned on, and the multiplexer 330 is turned off, thereby causing the write driver 110 to couple to the bit line BL 340 and to decouple from the bit line BL 350.

In some embodiments, the memory bank 180A may be physically located farther from the write driver 110 than the memory bank 180B. As such, the bit line BL 340 can be formed across multiple metallization layers to fly over the memory bank 180A. As a non-limiting example, the memory cells of both of the memory banks 180A-B may be formed along the major surface of a substrate, sometimes referred to as a part of a front-end-of-line (FEOL) network. The bit line BL 350 may be formed based on at least one first metal track disposed in a first one of plural metallization layers (e.g., M0 layer) disposed over the major substrate surface, sometimes referred to as a part of a back-end-of-line (BEOL) network. The bit line BL 340 may be formed based on at least a second metal track disposed in a second, higher one of plural metallization layers (e.g., M2 layer), a third metal track disposed in the first metallization layer (M0 layer), and one or more via structures connecting the second metal track to the third metal track.

Referring next to FIG. 4 (in conjunction with FIG. 3), two memory cells, e.g., 190A1, 190A2, 190B1, 190B2, are illustrated in each of the memory banks 180A and 180B. Continuing with the above example where the memory bank 180A and the memory bank 180B are selected to the active one and the inactive one, respectively, and the bit line BL 350 is applied with a logic low value, the bit line 350 may be applied with a negative bit line voltage of about −100 mV (e.g., by the write driver 110), while the BLB 340′ (of the active memory bank 180A) and the bit line pair, BL 350 and BLB 350′, are floating (e.g., staying at a pre-charged voltage level of around 1.1V). As such, the memory cell 190A1 closer to the write driver 110 may see the vBL signal present on its corresponding portion of the bit line BL 340 at around −100 mV, and the memory cell 190A2 farther from the write driver 110 may see the vBL signal present on its corresponding portion of the bit line BL 340 at around −50 mV (e.g., due to IR drop and/or leakage of the pass-gate devices disposed between the memory cell 190A2 and the write driver 110).

With their corresponding portions of the bit line 340 each presenting a negative bit line voltage, each of the memory cells 190A1 and 190A2 can be more efficiently programmed with a logic low value into its X node. On the other hand, each of the memory cells 190B1 and 190B2 sees its corresponding portion of the bit line BL 350 remaining at around 1.1V (the pre-charged voltage level). As the inactive memory bank 180B is powered by CVDD of around 0.5V, the node X of each of the memory cells 190B1 and 190B2 is latched at around 0.5V. Without the negative bit line voltage applied on the bit line 350, each of the memory cells 190B1 and 190B2 can thus safely retain its previously stored data.

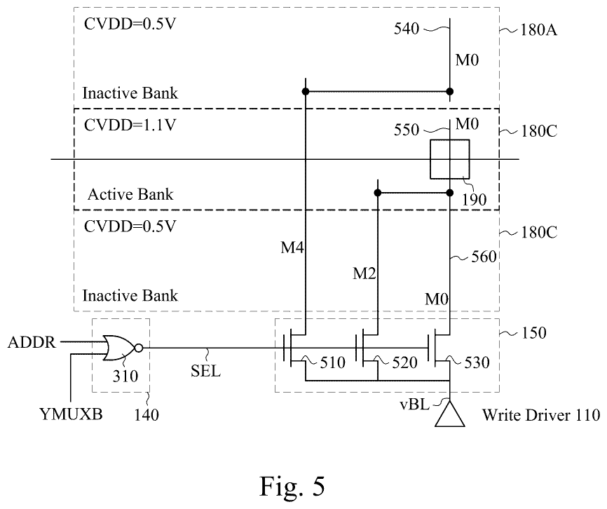

FIG. 5 illustrates an example schematic diagram of a portion of the SRAM device 100 (FIG. 1), in accordance with some embodiments of the present disclosure. In the example of FIG. 5, three memory banks, e.g., 180A, 180B, and 180C, are included in the memory array 180, one of which can be selected as an active one and the other two of which can each be selected as an inactive one. For example, the memory array 180 may include 256 rows (or 256 word lines), in which the memory bank 180B with 128 rows is selected as the active memory bank (e.g., operating with CVDD of about 1.1V), and the memory bank 180B with 64 rows and the memory bank 180C with 64 rows are each selected as the inactive memory bank (e.g., operating with CVDD of about 0.5V).

Similar to the schematic diagram of FIG. 3, the bank decoder 140 also includes the NOR gate 310 configured to NOR the received ADDR signal and MUXB signal providing the SEL signal to the bank multiplexer circuit 150. In FIG. 5, the bank multiplexer circuit 150 includes three multiplexers, 510, 520, and 530, that are coupled between the write driver 110 and a corresponding memory bank (or its bit line BL), respectively. Each of the multiplexers 510 to 530 may be implemented as an NMOS device, with its gate terminal configured to receive the SEL signal. Further, the multiplexer 510 can have its first and second source/drain terminals connected to the write driver 110 and a bit line BL 540 of the memory bank 180A, respectively; the multiplexer 520 can have its first and second source/drain terminals connected to the write driver 110 and a bit line BL 550 of the memory bank 180B, respectively; and the multiplexer 530 can have its first and second source/drain terminals connected to the write driver 110 and a bit line BL 550 of the memory bank 180C, respectively.

In some embodiments, the memory bank 180A may be physically located farther from the write driver 110 than the memory banks 180B and 180C, and the memory bank 180B may be physically located farther from the write driver 110 than the memory bank 180C. As such, the bit line BL 540 can be formed across multiple metallization layers to fly over the memory banks 180B-C, and the bit line BL 550 can also be formed across multiple metallization layers to fly over the memory bank 180C.

As a non-limiting example, the memory cells of all of the memory banks 180A-C may be formed along the major surface of a substrate. The bit line BL 560 may be formed based on at least one first metal track disposed in a first one of plural metallization layers (e.g., M0 layer) disposed over the major substrate surface. The bit line BL 550 may be formed based on at least a second metal track disposed in a second, higher one of plural metallization layers (e.g., M2 layer), a third metal track disposed in the first metallization layer (M0 layer), and one or more via structures connecting the second metal track to the third metal track. The bit line BL 550 may be formed based on at least a fourth metal track disposed in a third, higher one of plural metallization layers (e.g., M4 layer), a fifth metal track disposed in the first metallization layer (M0 layer), and one or more via structures connecting the fourth metal track to the fifth metal track.

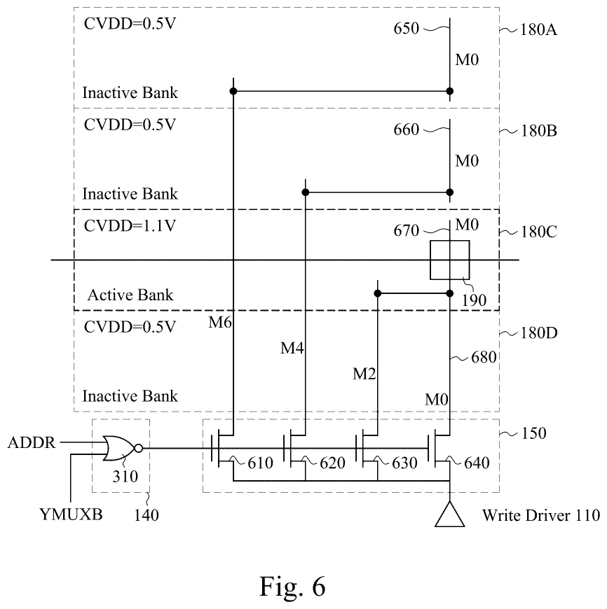

FIG. 6 illustrates an example schematic diagram of a portion of the SRAM device 100 (FIG. 1), in accordance with some embodiments of the present disclosure. In the example of FIG. 5, four memory banks, e.g., 180A, 180B, 180C, and 180D, are included in the memory array 180, one of which can be selected as an active one and the other three of which can each be selected as an inactive one. For example, the memory array 180 may include 256 rows (or 256 word lines), in which the memory bank 180C with 64 rows is selected as the active memory bank (e.g., operating with CVDD of about 1.1V), and the memory banks 180A, 180B, and 180D, with 64 rows, are each selected as the inactive memory bank (e.g., operating with CVDD of about 0.5V).

Similar to the schematic diagram of FIG. 3, the bank decoder 140 also includes the NOR gate 310 configured to NOR the received ADDR signal and MUXB signal providing the SEL signal to the bank multiplexer circuit 150. In FIG. 6, the bank multiplexer circuit 150 includes three multiplexers, 610, 620, 630, and 640, that are coupled between the write driver 110 and a corresponding memory bank (or its bit line BL), respectively. Each of the multiplexers 610 to 640 may be implemented as an NMOS device, with its gate terminal configured to receive the SEL signal. Further, the multiplexer 610 can have its first and second source/drain terminals connected to the write driver 110 and a bit line BL 650 of the memory bank 180A, respectively; the multiplexer 620 can have its first and second source/drain terminals connected to the write driver 110 and a bit line BL 660 of the memory bank 180B, respectively; the multiplexer 630 can have its first and second source/drain terminals connected to the write driver 110 and a bit line BL 670 of the memory bank 180C, respectively; and the multiplexer 640 can have its first and second source/drain terminals connected to the write driver 110 and a bit line BL 680 of the memory bank 180D, respectively.

In some embodiments, the memory bank 180A may be physically located farther from the write driver 110 than the memory banks 180B-D, the memory bank 180B may be physically located farther from the write driver 110 than the memory banks 180C-D, and the memory bank 180C may be physically located farther from the write driver 110 than the memory bank 180D. As such, the bit line BL 650 can be formed across multiple metallization layers to fly over the memory banks 180B-D, the bit line BL 660 can also be formed across multiple metallization layers to fly over the memory banks 180C-D, and the bit line BL 670 can also be formed across multiple metallization layers to fly over the memory bank 180D.

As a non-limiting example, the memory cells of all of the memory banks 180A-D may be formed along the major surface of a substrate. The bit line BL 680 may be formed based on at least one first metal track disposed in a first one of plural metallization layers (e.g., M0 layer) disposed over the major substrate surface. The bit line BL 670 may be formed based on at least a second metal track disposed in a second, higher one of plural metallization layers (e.g., M2 layer), a third metal track disposed in the first metallization layer (M0 layer), and one or more via structures connecting the second metal track to the third metal track. The bit line BL 680 may be formed based on at least a fourth metal track disposed in a third, higher one of plural metallization layers (e.g., M4 layer), a fifth metal track disposed in the first metallization layer (M0 layer), and one or more via structures connecting the fourth metal track to the fifth metal track. The bit line BL 650 may be formed based on at least a sixth metal track disposed in a fourth, higher one of plural metallization layers (e.g., M6 layer), a seventh metal track disposed in the first metallization layer (M0 layer), and one or more via structures connecting the sixth metal track to the seventh metal track.

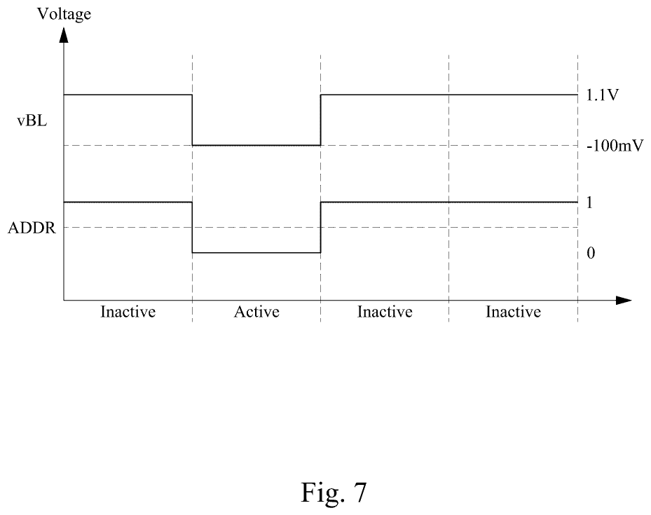

FIG. 7 illustrates example waveforms of the foregoing vBL signal and one bit of the ADDR signal, respectively, in accordance with some embodiments of the present disclosure. The bit of the ADDR signal may be configured to indicate whether a corresponding memory bank is configured as an active one (e.g., to be written). For example, when that bit of the ADDR signal is provided as logic 1, the corresponding memory bank is configured as an inactive one, causing the vBL to be provided at a pre-charged voltage level (e.g., about 1.1V); and when that bit of the ADDR signal is provided as logic 0, the corresponding memory bank is configured as an active one, causing the vBL to be provided at a negative voltage level (e.g., about −100 mV).

FIG. 8 illustrates an example circuit diagram of the foregoing write assist circuit of the write driver 110 (hereinafter “write assist circuit 800”), in accordance with some embodiments of the present disclosure. In general, the write assist circuit 800 can selectively provide the vBL signal with a negative voltage. It should be understood that the circuit diagram of FIG. 8 has been simplified for illustrative purposes. Thus, the write assist circuit 800 can include any of various other suitable components, while remaining within the scope of the present disclosure.

As shown, the write assist circuit 800 includes an NMOS device 810 (functioning as a switch) and a boost capacitor 820. The NMOS device 810 is coupled between ground and node A, and the boost capacitor 820 is coupled between the node A and node B which is connected to a gate terminal of the NMOS device 810. A bit line boost enable control signal 801 can be provided at node B from a logic circuit 830, which may be configured to receive a write enable signal 803 (e.g., a logic inverse to the YMUXB signal). The logic circuit 830 may include a number of delay elements connected in series with one or more inverters that provide a delay to the write enable signal 803. The write enable signal 803 can thus be delayed and inverted to provide a boost signal 805 at node B. Before the write enable signal 803 goes high (at the start of the write operation/period), the boost signal 805 is high, which turns on the NMOS device 810 and charges the boost capacitor 820. When the boost signal 805 is high, node A is also connected to ground through the NMOS device 810. After the delay, the boost signal 805 goes low, which turns off the NMOS device 810 and, at the same time, causes a discharge from the boost capacitor 820, which drives node A from ground (low) to a negative value. This negative voltage is then provided as the vBL signal and provided to the active memory bank as discussed above.

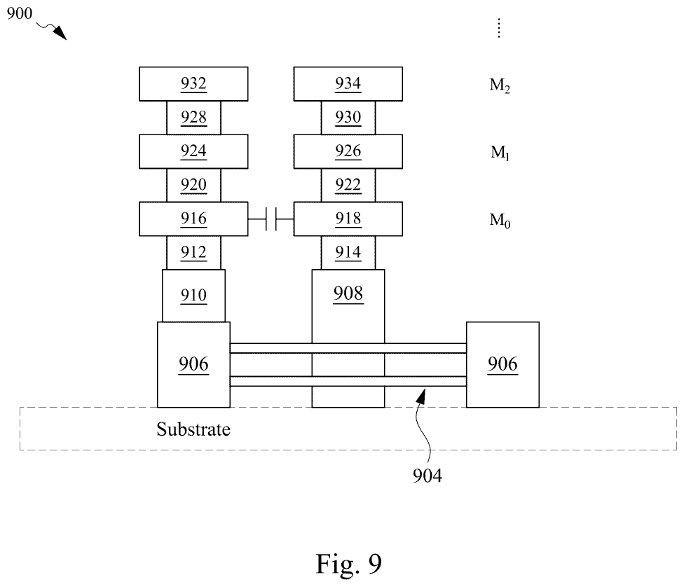

FIG. 9 illustrates a cross-sectional view of a semiconductor device 900 that may be implemented as at least a portion of the SRAM device 100. For example, the semiconductor device 900 may include various components configured as the write assist circuit of the write driver 110. The cross-sectional view of FIG. 9 is cut along the lengthwise direction of channels of a plurality of transistors of the semiconductor device 900, which are each implemented as a gate-all-around field-effect-transistor (GAA FET) device. However, it should be understood that the transistors of the semiconductor device 900 may be implemented as any of various other transistor structures (e.g., FinFETs, planar FETs, or otherwise nanostructure transistors, etc.), while reaming within the scope of the present disclosure.

On the frontside of a substrate (which is enclosed by a dotted line, as it has been removed when forming backside interconnect structures), the semiconductor device 900 includes an active region 902 having portions being formed as channels 904 and portions being formed as source/drain structures 906. The channels 904 can each include one or more nanostructures (e.g., nanosheets, nanowires) vertically spaced apart from each other, and the source/drain structures 906 can each include one or more epitaxial structures, in various embodiments. The semiconductor device 900 includes a number of active (e.g., metal) gate structures 908, each on which wraps around the nanostructures of a corresponding channel 904. Over the source/drain structure 906, the semiconductor device 900 includes a number of source/drain interconnect structures (sometimes referred to as MDs) 910, some of which are coupled with contact via structures (sometimes referred to as VDs) 912 formed thereupon. Over the gate structure 908, the semiconductor device 900 includes a number of gate via structures (sometimes referred to as VGs) 914.

The VD 912 can couple the MD 910 to a first metal track 916 in the first frontside metallization layer, M0 layer. The metal track 916 is sometimes referred to as M0 track 916. The VG 914 can couple the gate structure 908 to a second M0 track 918. Over the M0 tracks 916 and 918 (and various other metal tracks in the M0 layer), the semiconductor device 900 includes a number of via structures (sometimes referred to as V0s), 920 and 922, to couple the M0 tracks 916 and 918 to respective metal tracks in the next frontside metallization layer (M1 layer) farther away from the substrate (sometimes referred to as M1 tracks), 924 and 926. Further, over the M1 tracks 924 and 926 (and various other metal tracks in the M1 layer), the semiconductor device 900 includes a number of via structures (sometimes referred to as V1s), 928 and 930, to couple the M1 tracks 924 and 926 to respective metal tracks in the next frontside metallization layer (M2 layer) farther away from the substrate (sometimes referred to as M2 tracks), 932 and 934. Although three frontside metallization layers are shown, it should be understood that the semiconductor device 900 can include any number of frontside metallization layers.

The metal tracks formed across such frontside metallization layers can be configured to electrically couple different components of the SRAM device 100 (so as to route signals and/or deliver power), in accordance with various embodiments. Using the schematic diagram of FIG. 3 as a representative example, the bit line BL 340, flying over the memory bank 180B, can be formed by at least one M0 track and one M2 track. In another example, the bit line 350 can be formed by a least one M0 track. In accordance with some embodiments of the present disclosure, at least one of the channels 904, together with a corresponding one of the gate structures 908 wrapping around such a channel and with a corresponding pair of source/drain structures 906, can form the NMOS device 810 of the write assist circuit 800. The M0 tracks 916 and 918 can form one of a number of parallel connected sub-capacitors of the boost capacitor 820. The M0 tracks 916 and 918 may function as terminals of such a sub-capacitor, respectively.

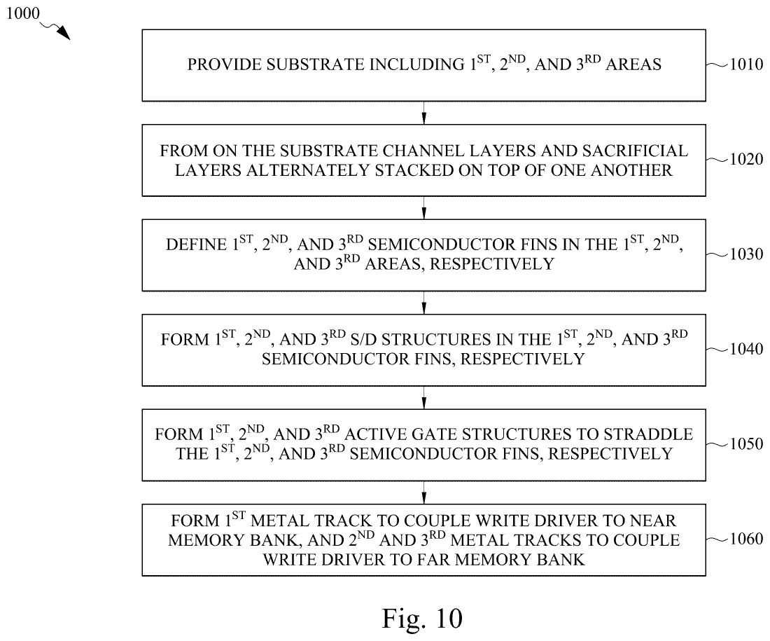

FIG. 10 illustrates a flowchart of an example method 1000 for forming or manufacturing a semiconductor device, in accordance with some embodiments. Some of the operations of the method 1000 can be configured to form at least a portion of the SRAM device 100 discussed above, e.g., the memory cells 190 of different memory banks 180A-B, the write driver 110, and the bit lines BLs 340-350 (FIGS. 3-4) coupling the write driver 110 to the memory banks 180A-B, the memory cells 190 of different memory banks 180A-C, the write driver 110, and the bit lines BLs 540-560 (FIG. 5) coupling the write driver 110 to the memory banks 180A-C, or the memory cells 190 of different memory banks 180A-D, the write driver 110, and the bit lines BLs 650-680 (FIG. 6) coupling the write driver 110 to the memory banks 180A-D. It is understood that additional operations may be performed before, during, and/or after the method 1000 depicted in FIG. 10.

For example, the method 1000 starts with operation 1010 of providing a substrate including a first area, a second area, and a third area. The method 1000 proceeds to operation 1020 of forming, on the substrate, channel layers and sacrificial layers alternatively stacked on top of one another. The method 1000 proceeds to operation 1030 of defining a number of first semiconductor fins, each including respective first portions of the channel layers and sacrificial layers, a number of second semiconductor fins, each including respective second portions of the channel layers and sacrificial layers, and a number of third semiconductor fins, each including respective third portions of the channel layers and sacrificial layers. In some embodiments, the first semiconductor fins may be disposed in the first area, the second semiconductor fins may be disposed in the second area, and the third semiconductor fins may be disposed in the third area.

The method 1000 proceeds to operation 1040 of forming a number of first source/drain structures in each of the first semiconductor fins, a number of second source/drain structures in each of the second semiconductor fins, and a number of third source/drain structures in each of the third semiconductor fins. The method 1000 can proceed to operation 1050 of forming a number of first active (e.g., metal) gate structures straddling the first semiconductor fins, a number of second active (e.g., metal) gate structures straddling the second semiconductor fins, and a number of third active (e.g., metal) gate structures straddling the third semiconductor fins. The first active gate structures can replace remaining portions of the sacrificial layers in the first semiconductor fins to wrap around remaining portions of the channel layers in the first semiconductor fins, the second active gate structures can replace remaining portions of the sacrificial layers in the second semiconductor fins to wrap around remaining portions of the channel layers in the second semiconductor fins, and the third active gate structures can replace remaining portions of the sacrificial layers in the third semiconductor fins to wrap around remaining portions of the channel layers in the third semiconductor fins.

In some embodiments, the first semiconductor fins, first source/drain structures, and first active gate structures can operatively form the first memory cells of a first memory bank; the second semiconductor fins, second source/drain structures, and second active gate structures can operatively form the second memory cells of a second memory bank; and the third semiconductor fins, third source/drain structures, and third active gate structures can operatively form a write driver. Further, the first area may be located between the second area and the third area, and thus, the first memory bank in the first area may sometimes be referred to as a near bank (with respect to the write driver), and the second memory bank in the second area may sometimes be referred to as a far bank (with respect to the write driver).

The method 1000 proceeds to operation 1060 of forming at least a first metal track in a first metallization layer that is configured to couple the write driver to the first memory bank, and at least a second metal track in a second, higher metallization layer and a third metal track in the first metallization layer that are configured to couple the write driver to the second memory bank. In some embodiments, the first metal track operatively serve as one of plural first bit lines of the first memory bank, and the second and third metal tracks can operatively serve as one of plural second bit lines of the first memory bank.

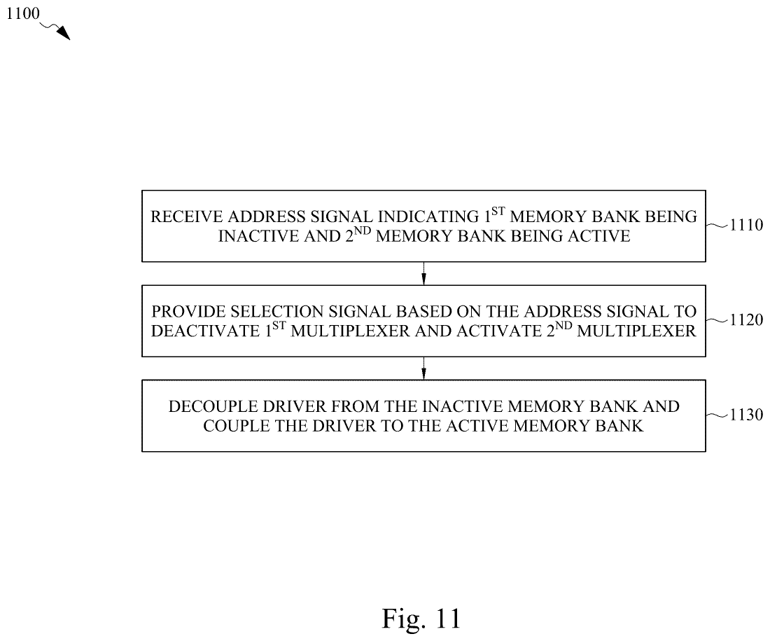

FIG. 11 illustrates a flowchart of an example method 1100 for operating a memory device, in accordance with some embodiments. For example, at least some of the operations of the method 1100 can be configured to selectively couple a write assist circuit that can provide a negative bit line voltage to one or more of various memory banks of a memory array, while decupling the negative bit line voltage from other of the memory banks. It is noted that the method 1100 is merely an example, and is not intended to limit the scope of the present disclosure. Accordingly, it should be understood that additional operations may be provided before, during, and/or after the method 1100 of FIG. 11, and that some other operations may only be briefly described herein.

The method 1100 starts with operation 1110 of receiving an address signal indicating a first memory array being an inactive memory bank and a second memory array being an active memory bank. In some embodiments, the inactive memory bank is configured to operate with a lower supply voltage and the active memory bank is configured to operate with a higher supply voltage. Using the implementation shown in FIG. 3 as a representative example, the bank decoder 140 can receive the ADDR signal including one or more bits each configured to indicate whether a corresponding memory bank is configured as an active or inactive bank. Based on the ADDR signal, the memory bank 180A may be indicated as the active memory bank, and the memory bank 180B may be indicated as the inactive memory bank. The active memory bank is configured for performing read/write operations, while the inactive memory bank is configured for retaining previously written data, according to some embodiments.

The method 1100 continues to operation 1120 of providing a selection signal based on the address signal to deactivate a first multiplexer and activate a second multiplexer. Continuing with the above example, the bank decoder 140 can provide the SEL signal to control (e.g., activate) the multiplexer 320, selectively coupling the write driver 110 to the memory bank 180A, and multiplexer 330, selectively coupling the write driver 110 to the memory bank 180B, based on the ADDR signal. The SEL signal may include first and second bits, and the first and second bits are logically inverse to each other. With the first bit provided at logic 1 (the second bit provided at logic 0), the multiplexer 320 is activated and the multiplexer 330 is deactivated.

The method 1100 continues to operation 1130 of decoupling, through the deactivated first multiplexer, a driver from the inactive memory bank so as to float a first bit line of the inactive memory bank, while coupling, through the activated second multiplexer, the driver to the active memory bank so as provide a negative voltage on a second bit line of the active memory bank. Continuing with the above example, when the multiplexer 320 is activated and the multiplexer 330 is deactivated, the write driver 110 can be configured to provide a negative bit line voltage and coupled to the memory bank 180A through the activated multiplexer 320. When the write driver 110 is configured to provide the negative bit line voltage, the write driver 110 may be concurrently decoupled from the memory bank 180B through the deactivated multiplexer 330.

In one aspect of the present disclosure, a memory circuit is disclosed. The memory circuit includes a first memory array comprising a plurality of first memory cells, each of which is configured to operate with a first supply voltage; a second memory array comprising a plurality of second memory cells, each of which is configured to operate with a second supply voltage, the first supply voltage and the second supply voltage being different from each other; and a driver operatively coupled to the plurality of first memory cells and the plurality of second memory cells through a first access line and a second access line, respectively. The driver is configured to selectively provide a negative voltage on one of the first access line or the second access line based on an address signal.

In another aspect of the present disclosure, a memory circuit is disclosed. The memory circuit includes a first memory array comprising a plurality of first memory cells coupled to one another through a first bit line; a second memory array comprising a plurality of second memory cells coupled to one another through a second bit line; and a driver operatively coupled to the first memory cells through the first bit line and to the second memory cells through the second bit line, wherein the first memory array and the second memory array are each physically located with respect to the driver along a lateral direction. The driver is configured to be decoupled from the first bit line, when the first memory array is configured as an inactive memory bank based on an address signal; and apply a negative voltage on the second bit line, when the second memory array is configured as an active memory bank based on the address signal.

In yet another aspect of the present disclosure, a method for operating a memory circuit is disclosed. The method includes receiving an address signal indicating a first memory array being an inactive memory bank and a second memory array being an active memory bank, wherein the inactive memory bank is configured to operate with a lower supply voltage and the active memory bank is configured to operate with a higher supply voltage. The method includes providing a selection signal based on the address signal to deactivate a first multiplexer and activate a second multiplexer. The method includes decoupling, through the deactivated first multiplexer, a driver from the inactive memory bank so as to float a first bit line of the inactive memory bank, while coupling, through the activated second multiplexer, the driver to the active memory bank so as provide a negative voltage on a second bit line of the active memory bank.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory circuit, comprising:
a first memory array comprising a plurality of first memory cells, each of which is configured to operate with a first supply voltage;
a second memory array comprising a plurality of second memory cells, each of which is configured to operate with a second supply voltage, the first supply voltage and the second supply voltage being different from each other; and
a driver operatively coupled to the plurality of first memory cells and the plurality of second memory cells through a first access line and a second access line, respectively;
wherein the driver is configured to selectively provide a negative voltage on one of the first access line or the second access line based on an address signal.

2. The memory circuit of claim 1, wherein the first memory cells and the second memory cells each include a static random access memory (SRAM) cell.

3. The memory circuit of claim 1, wherein the driver is physically located closer to one of the first or second memory array than the other of the first or second memory array along a lateral direction.

4. The memory circuit of claim 1, wherein the driver is configured to apply the negative voltage on the first access line through a first transistor turned on by the address signal, while being decoupled from the second access line through a second transistor turned off by the address signal.

5. The memory circuit of claim 1, wherein, with the first memory array interposed between the driver and the second memory array along a lateral direction, the first access line is formed of at least a first metal track physically extending along the lateral direction, and the second access line is formed of at least a second metal track and a third metal track both physically extending along the lateral direction.

6. The memory circuit of claim 5, wherein the first metal track and the third metal track are formed in a first metallization layer, with the second metal track formed in a second, higher metallization layer.

7. The memory circuit of claim 6, wherein the first metal track and second metal track both extend across the first memory array.

8. The memory circuit of claim 1, wherein the first memory array is configured as an active memory bank based on the address signal, causing the first access line to receive the negative voltage, while the second memory array is configured as an inactive memory bank based on the address signal, causing the second access line to be floating.

9. The memory circuit of claim 1, further comprising:
a logic gate configured to provide a selection signal based on the address signal, wherein the address signal indicates whether to select the second memory array as an active memory bank;
a first transistor configured to decouple the driver from the first access line based on the selection signal; and
a second transistor configured to couple the driver to the second access line based on the selection signal.

10. The memory circuit of claim 9, wherein the logic gate is configured to perform a NOR operation on the address signal and a control signal.

11. The memory circuit of claim 9, wherein the first transistor and the second transistor are alternately turned on based on the address signal.

12. A memory circuit, comprising:
a first memory array comprising a plurality of first memory cells coupled to one another through a first bit line;
a second memory array comprising a plurality of second memory cells coupled to one another through a second bit line; and
a driver operatively coupled to the first memory cells through the first bit line and to the second memory cells through the second bit line, wherein the first memory array and the second memory array are each physically located with respect to the driver along a lateral direction;
wherein the driver is configured to:
be decoupled from the first bit line, when the first memory array is configured as an inactive memory bank based on an address signal; and
apply a negative voltage on the second bit line, when the second memory array is configured as an active memory bank based on the address signal.

13. The memory circuit of claim 12, wherein the driver is physically located closer to one of the first or second memory array than the other of the first or second memory array along a lateral direction.

14. The memory circuit of claim 12, wherein, with the first memory array interposed between the driver and the second memory array along a lateral direction, the first bit line is formed of at least a first metal track physically extending along the lateral direction, and second bit line is formed of at least a second metal track and a third metal track both physically extending along the lateral direction.

15. The memory circuit of claim 14, wherein the first metal track and the third metal track are formed in a first metallization layer, with the second metal track formed in a second, higher metallization layer.

16. The memory circuit of claim 15, wherein the first metal track and second metal track both extend across the first memory array.

17. The memory circuit of claim 12, further comprising:
a logic gate configured to provide a selection signal based on the address signal;
a first transistor selectively coupled between the driver and the first bit line based on the selection signal; and
a second transistor selectively coupled between the driver and the second bit line based on the selection signal.

18. A method for operating a memory circuit, comprising:
receiving an address signal indicating a first memory array being an inactive memory bank and a second memory array being an active memory bank, wherein the inactive memory bank is configured to operate with a lower supply voltage and the active memory bank is configured to operate with a higher supply voltage;
providing a selection signal based on the address signal to deactivate a first multiplexer and activate a second multiplexer; and
decoupling, through the deactivated first multiplexer, a driver from the inactive memory bank so as to float a first bit line of the inactive memory bank, while coupling, through the activated second multiplexer, the driver to the active memory bank so as provide a negative voltage on a second bit line of the active memory bank.

19. The method of claim 18, wherein the first memory array is physically located between the second memory bank and the driver along a lateral direction.

20. The method of claim 19, wherein the first bit line is formed of at least a first metal track physically extending along the lateral direction, and the second bit line is formed of at least a second metal track and a third metal track both physically extending along the lateral direction, and wherein the first and third metal tracks are formed in a first metallization layer, with the second metal track formed in a second, higher metallization layer.
